(19) United States
(12) Patent Application Publication
(10) Pub. No.: US 2024/0240116 A1
(43) Pub. Date: Jul. 18, 2024

(54) COMPOSITION FOR DEFLUXING ELECTRONIC ASSEMBLIES

(71) Applicant: DEHON, Paris (FR)

(72) Inventors: Christophe DEHON, BRY-SUR-MARNE (FR); Marine D'AMICO, NOISY LE GRAND (FR); Laura Jacqueline LECOMTE, NOISY LE GRAND (FR)

(21) Appl. No.: 18/289,552

(22) PCT Filed: May 2, 2022
(86) PCT No.: PCT/EP2022/061715

§ 371 Date: Nov. 3, 2023

(30) Foreign Application Priority Data
May 5, 2021 (FR) FR2104740

(51) Int. Cl. C11D 7/50; C11D 7/26; C11D 7/34; C11D 7/36; H05K 3/26

(52) U.S. Cl. CPC C11D 7/5022; C11D 7/263; C11D 7/266; C11D 7/267; C11D 7/34; C11D 7/36; C11D 7/5009; H05K 3/26

(57) ABSTRACT

The invention relates to a composition intended for the cleaning of contaminants and flux residues on electronic assemblies, particularly solder cream residue. Said composition comprises:
from 20% to 99.5% by weight of a main solvent consisting of at least a C6-C15 glycol ether, and optionally a secondary solvent,
from 0.5% to 20% by weight of a selected acid additive which is a phosphoric acid ester. The invention also relates to a defluxing product incorporating said composition, as well as to the defluxing methods using these products

The present invention belongs to the field of manufacturing electronic boards and component assemblies and more particularly to the field of cleaning solder flux residues after soldering components.

It has for purpose a composition intended for cleaning contaminants and flux residues on electronic assemblies, in particular solder cream residues. It also relates to a defluxing product incorporating said composition, as well as the defluxing methods using these products.

The manufacture of electronic boards and other assemblies requires many steps during which they may be contaminated by various products used or generated during the process, such as oxides, organic residues or residues of substances used when soldering components to strip the surfaces and improve the quality of the junctions. In particular, the assembly and soldering of components uses compositions called soldering or welding fluxes, which may be in liquid form or in the form of a cream integrated into the filler metal, and which produce residues adhering to the electronic components and to the support. This leads to a loss in reliability of the assemblies, due to the formation of dendrites, among other things, which may lead to short circuits. These residues must therefore be carefully removed by a so-called defluxing operation.

However, the new component typologies are seeking ever higher performance with ever more functionalities: capacitors, diodes, quartz, micro-electromechanical systems (MEMs), micro-ball grid arrays (μBGAs), flip chips, light emitting diodes (LEDs) and others. Simultaneously, the miniaturization of electronic assemblies results in reduced spaces between component legs, decreased interstitial spaces (or stand-offs) under components, and creates substantial and difficult-to-access flux retention areas. However, this miniaturization must not affect the reliability of the assemblies, which requires that the level of cleanliness obtained after defluxing remains compliant with the different quality standards required by manufacturers and regulations, despite the increasing complexity it represents. Cleaning electronic circuits and assemblies is a new technological challenge in this context.

Currently used fluxing methods are divided into two main categories. On the one hand, so-called “solvent methods” and, on the other hand, aqueous methods. In the case of solvent methods, defluxing is carried out by immersion with a solvent in the vapor phase, or with a solvent and a co-solvent used in a mixture or separately. Commonly, an organic solvent is used in combination with a fluorinated or chlorinated co-solvent with a rinsing function. In the case of aqueous methods, there are two main families of techniques, i.e. immersion techniques carried out in a tank, in which case cleaning is carried out by mechanical action using immersed jets or ultrasound; and spraying techniques carried out by in-line treatment or in cycles (called “in-line” and “off-line”). Each type of method requires the use of a suitable cleaning product. Thus, for solvent methods in the vapor phase, solvents miscible with fluorinated or chlorinated solvents used for rinsing parts are used, which are generally low-polar and therefore poorly miscible in water. For aqueous immersion or spray methods, detergents are used that implement saponofiers or water-miscible solvents, at least under certain conditions.

There is therefore a variety of residue cleaning methods that use different equipment and different products. A method is selected based on several parameters, including component compatibility, production rate, and HSE (health, safety and environment) criteria.

The type of flux to be cleaned is of course a decisive parameter, which itself depends on the nature of the parts to be assembled (alloy type and surface condition) and the melting temperature of the filler metal. Indeed, some types of cream are difficult to clean with detergents, whereas, conversely, other types of cream are resistant to solvents in vapor phase. In addition, these cleaning methods use detergents or solvents, which raises issues with environmental regulations, such as water consumption, VOC (volatile organic compounds) emission levels, etc.

Despite the variety of existing methods, the removal of solder flux remains particularly difficult. Therefore, there is a need for electronic board and assembly manufacturers to have a defluxing composition with a versatile nature and improved effectiveness for the removal of soldering cream residue, fluxes and contaminants of all kinds.

The purpose of the present invention is to overcome the problems set forth above by proposing an effective defluxing product for cleaning complex and highly miniaturized electronic assemblies. Another aim of the invention is to propose a defluxing product capable of cleaning a wide range of flux residues, coming from both liquid fluxes and solder creams. Another purpose of the invention is to offer a versatile composition suitable for various defluxing methods, in particular for spraying, immersion and vapor-phase cleaning methods. Another purpose of the invention is to enable the treatment of a large number of materials, firstly metals and polymers commonly used for electronic circuits. A product is also sought that meets the safety and health standards of personnel and that has a reduced impact on the environment.

The present invention proposes to meet the objectives set out above through a composition intended for defluxing boards and other electronic assemblies, comprising one or more solvents, associated with an additive the particularity of which is to provide an acidic nature to said composition, unlike known defluxing agents which are alkaline or neutral.

The defluxing products conventionally used are indeed alkaline detergents containing organic solvents, surfactants, bases and various additives having the function of avoiding undesirable effects such as foaming, redeposition of contaminants, etc. For example, US2018/298310 describes a composition comprising isopropylidene glycerol and an alkali such as an amine or a salt, in an amount ensuring a pH greater than 7.5. The composition may contain a secondary solvent which may be a glycol ether of a determined formula. US2019/136159 discloses a composition for removing contaminants from electronic assemblies, containing butylpyrrolidone and an amine or hydroxide in an amount suitable for the pH to be greater than 7 with a pKa lower than 12. Neutral pH cleaning products, containing organic solvents such as glycol ethers, are also proposed.

Unexpectedly, a defluxing composition containing an acid additive proved to be highly effective and furthermore possess excellent activity with respect to a large number of fluxes to be removed. It has been successfully used in both aqueous and anhydrous methods, as a cleaning product in its pure state, diluted in aqueous phase or in a mixture with co-solvents. It may be assumed that more effective particular reaction mechanisms are implemented due to the acidic nature of the additive acting as a cleaning agent, and the cleaning composition itself. Furthermore, when the composition is used in an aqueous medium, the acid additive provides a deoxidizing action of the substrates. The present invention therefore offers a very active and versatile composition, particularly advantageous with respect to conventional defluxing compositions.

More precisely, the invention has as its first object a composition intended for cleaning contaminants and flux residues on electronic assemblies remarkable in what it comprises, relative to the total weight of the composition: from 20% to 99.5% by weight of a main solvent consisting of at least one C6-C15 glycol ether, and optionally a secondary solvent,
from 0.5% to 20% by weight of an acid additive being a phosphoric acid ester.

The composition therefore comprises a solvent qualified as a main solvent, and possibly a second solvent, said secondary solvent, which are associated with an additive the particularity of which is to be an acidic compound. As a result, the cleaning composition itself has a strongly acidic nature, unlike the usual defluxing compositions and products that are alkaline or neutral, as seen above. The main solvent may consist of a single compound or a mixture of several compounds. It may be used alone or with a secondary solvent.

Preferably, the object of the invention is a composition intended for cleaning contaminants and flux residues on electronic assemblies, comprising, relative to the total weight of the composition:
from 40% to 99.5% by weight of a main solvent consisting of at least one C6-C15 glycol ether,
from 0% to 50% by weight of a secondary solvent,
from 0.5% to 20% by weight of an acid additive being a phosphoric acid ester

It is specified that in the following description, the terms “composition”, “defluxing composition” or “cleaning composition” refer to the mixture of the main solvent, and possibly the secondary solvent, with the acid additive chosen, such as defined above. The acid additive may also be referred to as “defluxing additive”. This composition is intended for cleaning electronic assemblies in that it may be used to obtain a “defluxing product” implemented in a defluxing method. According to the particular method concerned, and as will be seen later, the pure composition may constitute as such a defluxing product, or it may be diluted in water, or combined with other compounds and/or solvent to form said defluxing product. With respect to electronic assemblies, the terms “cleaning” and “defluxing” are used indifferently.

According to preferred embodiments, the composition comprises, relative to the total weight of the composition, at least 0.8% by weight of an acid additive being a phosphoric acid ester; preferably at least 1% by weight; preferably at least 2% by weight; preferably at least 3% by weight; preferably at least 5% by weight; preferably at least 8% by weight.

According to preferred embodiments, the composition comprises, relative to the total weight of the composition, at most 18% by weight of an acid additive being a phosphoric acid ester; preferably at most 16% by weight; preferably at most 15% by weight; preferably at most 12% by weight; preferably at most 10% by weight; preferably at most 8% by weight, preferably at most 5% by weight.

According to preferred embodiments, the composition comprises, relative to the total weight of the composition, from 0.8% to 18% by weight of an acid additive being a phosphoric acid ester; preferably from 1% to 16% by weight; preferably from 2% to 15% by weight; preferably from 3% to 12% by weight. For example, the composition comprises from 0.5% to 10% by weight of an acid additive being a phosphoric acid ester; preferably from 0.8% to 8%; preferably from 1% to 5%. For example, the composition comprises from 3% to 20% by weight of an acid additive being a phosphoric acid ester; preferably from 5% to 18%; preferably from 8% to 15% by weight; preferably from 10% to 20% by weight.

According to a preferred embodiment of the invention, said acid additive is a phosphoric acid ester of general formula R1-O—POOH—O—R2, wherein R1 represents a C1-C25 radical and R2 is a hydrogen atom, or wherein R1 and R2 represent identical or different C1-C25 radicals.

According to a more preferred embodiment of the invention, said acid additive may be a phosphoric acid ester of general formula R1-O—POOH—O—R2, wherein R1 represents a C4-C16 radical and R2 is a hydrogen atom, or wherein R1 and R2 represent identical or different C4-C16 radicals.

The radicals R1 and R2 other than a hydrogen may be aliphatic, linear, branched, or cyclic hydrocarbon groups (i.e. comprising several carbon and hydrogen atoms). These hydrocarbon chains may be ethoxylated or propoxylated.

According to a particularly preferred characteristic of the composition object of the invention, said acid additive may be chosen from phosphoric acid 2-ethylhexyl ester; poly(oxy-1,2-ethanediyl), phosphoric acid alpha-(2-ethylhexyl)-omega ester; phosphoric acid n-octyl ester; phosphoric acid methyl ester; phosphoric acid polyoxyethylene monooleyl ether, or a mixture thereof.

Preferably, the acid additive may be chosen from phosphoric acid 2-ethylhexyl ester; poly(oxy-1,2-ethanediyl), phosphoric acid alpha-(2-ethylhexyl)-omega ester; phosphoric acid n-octyl ester; phosphoric acid methyl ester; phosphoric acid polyoxyethylene monooleyl ether. In particular, use may be made of phosphoric acid 2-ethylhexyl ester wherein R1 is a group of empirical formula C8H19 and R2 is a hydrogen atom.

Thus, preferably, said acid additive is or comprises phosphoric acid 2-ethyl hexyl ester.

This acid additive is accompanied by at least one main solvent which is capable of solubilizing the additive in question. However, some acid additives are difficult to solubilize in the solvent phase, as is the case in particular with phosphoric acid esters. This acid additive may be solubilized by a well-chosen combination of the additive and the solvent—main solvent and possibly secondary solvent. This then gives the composition a strongly acidic nature, contrary to use in the field of defluxing. In doing so, surprisingly, the composition demonstrates a high cleaning effectiveness.

The main solvent is a glycol ether or a mixture of glycol ethers. Glycol ethers are frequently used in products intended for defluxing because they have good flux residue solubilization capabilities. Many of them having a carbon chain of 6 to 15 atoms may be suitable, but lighter compounds, having 6 to 10 carbon atoms, will be preferred.

Thus, according to an advantageous characteristic of the composition object of the invention, the main solvent may be a C6-C10 glycol ether or a mixture of two C6-C10 glycol ethers, each chosen from a tripropylene glycol, dipropylene glycol, propylene glycol, diethylene glycol, ethylene glycol or butylene glycol ether.

Preferably, the glycol ether is selected from tripropylene glycol n-butyl ether; dipropylene glycol monomethyl ether; dipropylene glycol dimethyl ether; dipropylene glycol monopropyl ether; dipropylene glycol n-butyl ether; dipropylene glycol phenyl ether; propylene glycol n-butyl ether; propylene glycol n-butyl ether; propylene glycol phenyl ether; diethylene glycol monobutyl ether; diethyleneglycol monohexyl ether; diethyleneglycol phenyl ether; ethyleneglycol mono tert-butyl ether; ethyleneglycol monohexyl ether; ethyleneglycol phenyl ether; butyleneglycol phenyl ether.

It is specified that the main solvent may consist of one of the compounds mentioned above, or several of them in mixture in various proportions. For example, a mixture of equal parts of propyl ether and dipropylene glycol n-butyl ether may be used. In general, compounds the toxicity of which poses no problem may be selected.

According to preferred embodiments, the composition comprises, relative to the total weight of the composition, at least 30% by weight of a main solvent consisting of at least one C6-C15 glycol ether; preferably at least 40% by weight; preferably at least 50% by weight; preferably at least 55% by weight; preferably at least 60% by weight; preferably at least 65% by weight, preferably at least 68% by weight; preferably at least 70% by weight.

According to preferred embodiments, the composition comprises, relative to the total weight of the composition, at most 99% by weight of a main solvent consisting of at least one C6-C15 glycol ether; preferably at most 98% by weight; preferably at most 95% by weight; preferably at most 93% by weight; preferably at most 90% by weight; preferably at most 88% by weight, preferably at most 85% by weight.

According to preferred embodiments, the composition comprises, relative to the total weight of the composition, from 30% to 99% by weight of a main solvent consisting of at least one C6-C15 glycol ether; preferably from 40% to 98% by weight; preferably from 50% to 95% by weight; preferably from 55% to 93% by weight; preferably from 60% to 90% by weight; preferably from 65% to 88% by weight; preferably from 68% to 85% by weight; preferably from 70% to 85% by weight; preferably from 40% to 99.5% by weight.

In a particular embodiment, the composition according to the invention may comprise only a main solvent and an additive. In this case, it may be composed, relative to the total weight of the composition:
from 80% to 99.5% by weight of said main solvent, and
from 0.5% to 20% by weight of said acid additive.

Preferably, it is composed, relative to the total weight of the composition:
from 85% to 99.5% by weight of said main solvent, and
from 0.5% to 15% by weight of said acid additive.

Preferably, it is composed, relative to the total weight of the composition:
from 90% to 99.5% by weight of said main solvent, and
from 0.5% to 10% by weight of said acid additive.

Preferably, it is composed, relative to the total weight of the composition:
from 80% to 99% by weight of said main solvent, and
from 1% to 20% by weight of said acid additive.

Such a composition is perfectly satisfactory for the removal of flux residues from electronic boards and assemblies and may be used as such for the preparation of a defluxing product. However, it is often convenient to combine a secondary solvent with it to facilitate rinsing operations. That is why, according to an interesting embodiment, the composition object of the invention may comprise a main solvent as described above and a secondary solvent. The mixing of solvents makes it possible to enhance the cleaning and rinsing action of flux residues.

According to one embodiment, the composition does not comprise a secondary solvent.

According to embodiments, the composition comprises a secondary solvent. When the secondary solvent is present, the composition preferably comprises, relative to the total weight of the composition, at least 1% by weight of a secondary solvent; preferably at least 3% by weight; preferably at least 5% by weight; preferably at least 7% by weight; preferably at least 9% by weight; preferably at least 10% by weight, preferably at least 12% by weight; preferably at least 13% by weight.

According to preferred embodiments, the composition preferably comprises, relative to the total weight of the composition, at most 70% by weight of a secondary solvent; preferably at most 60% by weight; preferably at most 50% by weight; preferably at most 45% by weight; preferably at most 40% by weight; preferably at most 35% by weight; preferably at most 30% by weight; preferably at most 28% by weight, preferably at most 25% by weight.

According to preferred embodiments, the composition comprises, relative to the total weight of the composition, from 0% to 70% by weight of a secondary solvent; preferably from 0% to 60% by weight; preferably from 0% to 50% by weight; preferably from 1% to 50% by weight; preferably from 3% to 45% by weight; preferably from 5% to 40% by weight; preferably from 7% to 35% by weight; preferably from 9% to 30% by weight; preferably from 10% to 25% by weight; preferably from 12% to 28% by weight; preferably from 13% to 25% by weight.

Advantageously, the composition comprises, relative to the total weight of the composition, from 1% to 70% of a secondary solvent chosen from a dibasic ester, a C3-C20 acetal, dimethylsulfoxide, or a mixture thereof; preferably from 5% to 70%; preferably from 7% to 50% by weight. For example, the secondary solvent chosen from a C3-C20 acetal, dimethylsulfoxide, or a mixture thereof. Preferably, the secondary solvent chosen from a dibasic ester, C3-C20 acetal, or a mixture thereof. Preferably, the secondary solvent comprises at least one C3-C20 acetal, or a mixture of one or more C3-C20 acetals.

The dibasic ester is traditionally a mixture resulting from the mass reaction between dimethyl glutarate, dimethyl adipate and dimethyl succinate, marketed as such.

Preferably, the secondary solvent may be chosen from tetraoxaundecane; dimethoxymethane (or methylal); diethoxymethane (or ethylam); dipropoxymethane (propylal); dibutoxymethane (or butylal), 2-ethyl hexylal (or 3,3′-[methylenebis(oxymethylene)]biseptane); 1,3-dioxolane, or a mixture thereof. More preferably, the secondary solvent may be chosen from tetraoxaundecane; 1,3-dioxolane, or a mixture thereof.

The composition according to the invention may be formulated in different proportions, so as to comprise, relative to the total weight of the composition:
from 40% to 90% by weight of said main solvent,
from 20% to 50% by weight of said secondary solvent, and
from 0.5% to 20% by weight of said acid additive.

Preferably, the composition comprises, relative to the total weight of the composition:
from 40% to 90% by weight of said main solvent,
from 7% to 50% by weight of said secondary solvent, and
from 0.5% to 15% by weight of said acid additive

More preferably, the composition comprises, relative to the total weight of the composition:
from 40% to 90% by weight of said main solvent,
from 7% to 50% by weight of said secondary solvent, and
from 0.5% to 10% by weight of said acid additive.

According to a preferred embodiment, the composition object of the invention comprises, relative to the total weight of the composition:
from 65% to 90% by weight of said main solvent,
from 9% to 30% by weight of said secondary solvent, and
from 1% to 15% by weight of said acid additive.

Preferably, the composition object of the invention comprises, relative to the total weight of the composition:
from 65% to 90% by weight of said main solvent,
from 9% to 30% by weight of said secondary solvent, and
from 1% to 10% by weight of said acid additive.

Preferably, the composition object of the invention comprises, relative to the total weight of the composition:
from 65% to 90% by weight of said main solvent,
from 9% to 30% by weight of said secondary solvent, and
from 1% to 5% by weight of said acid additive.

According to a preferred embodiment, the composition object of the invention comprises, relative to the total weight of the composition:
from 65% to 90% by weight of said main solvent,
from 5% to 25% by weight of said secondary solvent, and
from 1% to 15% by weight of said acid additive.

According to a particularly preferred embodiment of the invention, the composition may comprise, relative to the total weight of the composition:
from 60% to 98% by weight of a C6-C10 glycol ether chosen from a tripropylene glycol, dipropylene glycol, propylene glycol, diethylene glycol, ethylene glycol or butylene glycol ether,
from 1% to 25% by weight of a secondary solvent chosen from 1,3-dioxolane, tetraoxaundecane, dimethylsulfoxide, a dibasic ester, or a mixture thereof, and
from 1% to 15% by weight of a phosphoric acid ester.

Preferably, the composition may comprise, relative to the total weight of the composition:
from 70% to 85% by weight of a C6-C10 glycol ether chosen from a tripropylene glycol, dipropylene glycol, propylene glycol, diethylene glycol, ethylene glycol or butylene glycol ether,
from 13% to 25% by weight of a secondary solvent chosen from 1,3-dioxolane, tetraoxaundecane, dimethylsulfoxide, a dibasic ester, or a mixture thereof, and
from 1% to 15% by weight of a phosphoric acid ester.

Preferably, the composition may comprise, relative to the total weight of the composition:
from 70% to 85% by weight of a C6-C10 glycol ether chosen from a tripropylene glycol, dipropylene glycol, propylene glycol, diethylene glycol, ethylene glycol or butylene glycol ether,
from 13% to 25% by weight of tetraoxanedecane, dimethylsulfoxide or dibasic ester, and
from 1% to 5% by weight of a phosphoric acid ester.

The preferred formulations presented here were chosen due to two essential criteria, namely on the one hand their performance in terms of cleaning effectiveness and on the other hand their low environmental impact (toxicity, flammability, pollution).

The composition described above is effective without the addition of other additives or technological and/or chemical additives, but it may optionally incorporate additional additives to improve some of its properties such as rinsability, effectiveness on particular pollutants, stability over time and maintaining the pH, etc. These additional additives are well known to those skilled in the art who will know how to select and use them wisely.

It was further observed that the formation of foam, undesirable in aqueous methods, was avoided when using the composition according to the invention. Indeed, it is interesting to note that most of the known products cause the formation of foam at room temperature, which is not the case with the inventive composition. It is therefore possible to use it to perform defluxing at temperatures from 25° C. to 40° C., this modality allowing significant energy savings, despite a treatment time that must be extended. However, to achieve optimum defluxing effectiveness in a minimum time, it is advisable to work at a temperature of around 50° C. to 60° C.

Originally, the composition object of the invention may be used for cleaning boards and other electronic assemblies, in the various usual defluxing methods. Depending on the method in question, it may be used as a cleaning product, either in its pure state, or diluted in aqueous phase, or in combination with a co-solvent.

Preferably, the composition shows an acid the value less than or equal to 50 mgKOH/g; preferably less than or equal to 45 mgKOH/g; preferably less than or equal to 40 mgKOH/g; preferably less than or equal to 35 mgKOH/g.

Advantageously, the composition has an acid the value between 1.8 and 50 mgKOH/g; preferably between 2.0 and 45 mgKOH/g; preferably between 2.2 and 40 mgKOH/g; preferably between 2.5 and 35 mg KOH/g.

That is why a second object of the invention relates to a remarkable electronic assembly defluxing product in that it comprises a composition such as described in the first object, and wherein:
said composition is pure; or
said composition is diluted in water to obtain a cleaning solution having a pH less than or equal to 5; or
said composition is mixed with a fluorinated or chlorinated rinsing co-solvent.

Thus, the invention relates to a defluxing product of electronic assemblies comprising a composition such as described previously diluted in water and having a pH less than or equal to 5; preferably less than or equal to 4.8; preferably less than or equal to 4.5; preferably less than or equal to 4.2 and more preferably less than or equal to 4; more preferably less than or equal to 3.8; more preferably less than or equal to 3.6.

Preferably, the defluxing product according to the invention comprises a composition as described previously diluted in water and comprising a pH greater than or equal to 1 and less than or equal to 5; preferably between 1.5 and 4.8; preferably between 1.8 and 4.5; preferably between 2.0 and 4.2; preferably between 2.2 and 4.0; or between 2.5 and 4.0.

When used as a cleaning product in aqueous solution, its dilution may typically range from 5 to 10 times (10% to 20%). These cleaning solutions prepared from the composition according to the invention have a clearly acidic pH, i.e. less than 5 and typically between 2 and 4.

This acid nature is also present when it is in its pure state or mixed with a co-solvent. Surprisingly, although most solder creams have an acidic pH, the residues of these creams were perfectly removed by the defluxing products according to the invention, with results as satisfactory, if not better, than with the alkaline or neutral products normally used.

Preferably, when the composition is in the pure state or mixed with a co-solvent, it shows an acid value less than or equal to 50 mgKOH/g; preferably less than or equal to 45 mgKOH/g; preferably less than or equal to 40 mgKOH/g; preferably less than or equal to 35 mgKOH/g.

Preferably, when the composition is in the pure state or mixed with a co-solvent, it shows an acid value between 1.8 and 50 mgKOH/g; preferably between 2.0 and 45 mgKOH/g; preferably between 2.2 and 40 mgKOH/g; preferably between 2.5 and 35 mgKOH/g.

The developed composition was successfully tested in the diluted state in spray defluxing methods, either in-line or in-cycle (batch). The solutions obtained are also satisfactory during immersion defluxing. In this case, it is recommended to provide mechanical agitation, for example by submerged jets or by recirculation pump. The treatment temperature is commonly 55° C., but other values may be set, for example between 30° C. and 70° C., and preferably between 50° C. and 65° C. The duration of the treatment is variable, ranging from a few minutes to around twenty minutes, and may be adjusted as needed. The experimental results show a substantially increased effectiveness of the tested defluxing compositions and solutions, with shorter treatment times at lower concentration compared to standard market detergents. That is why these methods are also the object of the present invention.

Thus, the third object of the present invention relates to an aqueous method for cleaning contaminants and flux residues on electronic assemblies that is remarkable in that it comprises the steps consisting of:
obtaining a composition according to the first object and diluting it in water to obtain a cleaning solution with a concentration between 5% and 30% by weight relative to the total weight of the solution,
subjecting said assemblies to a cleaning treatment by immersion or by spraying with said cleaning solution at a temperature between 30° C. and 70° C., for 1 min to 20 min.

A rinsing step and a drying step are conventionally added to this cleaning step.

For example, said composition is diluted in water to obtain a cleaning solution of a concentration between 10% and 20% by weight relative to the total weight of the solution.

For example, said assemblies are subjected to a cleaning treatment by immersion or by spraying with said cleaning solution at a temperature between 50° C. and 65° C., for 3 min to 10 min.

Particularly originally, the composition object of the invention may also be used in a defluxing product in anhydrous methods (therefore without aqueous dilution). In this case, it is implemented in combination with a rinsing co-solvent, separately (and successively) or as a mixture (simultaneously). Rinsing solvents, in particular chlorinated or fluorinated, may be mixed with the composition object of the invention because the latter is fully soluble at high contents, advantageously between 50% and 70% by weight. It is interesting that the secondary solvent—when present in the composition—also has good solubility, so that the product as a whole is soluble in the co-solvent. Fluorinated rinsing co-solvents are preferred, particularly hydrofluoroethers (HFE), hydrofluorocarbons (HFC) or hydrofluorolefins (HFO).

Such a co-solvent in mixture has proven to have a boiling temperature comparable to that of formulations used up to now, typically between 60° C. and 75° C. Since the temperature of the defluxing treatment is set at a value close to the boiling temperature of the solvent or co-solvent, it will be easy to replace the conventional products with the inventive composition, without having to modify the operating protocol.

The experimental results show that cleaning products comprising the composition according to the invention are more effective than products commonly used in co-solvent methods on the market. In addition, due to the nature of the components chosen, it has less impact on the environment.

That is why a fourth object of the invention relates to an anhydrous method for cleaning contaminants and flux residues on electronic assemblies that is remarkable in that it comprises the steps consisting of:
obtaining a composition according to the first object and a fluorinated rinsing co-solvent,
subjecting said assemblies to a vapor phase co-solvent cleaning treatment with said undiluted composition and said co-solvent, used successively or simultaneously, at a temperature between 50° C. and 80° C., for 1 min to 20 min.

The composition and the rinsing co-solvent may be mixed in various proportions, the composition may represent from 40% to 90% by weight relative to the total weight of the cleaning product, but levels ranging from 50% to 70% by weight will preferably be maintained. Defluxing and rinsing are then performed in the same bath.

Thus, according to the invention, the anhydrous cleaning method may be conducted according to the modalities by which:
said composition is mixed with a co-solvent chosen from hydrofluoroethers, hydrofluorocarbons or hydrofluorolefins, the composition representing from 50% to 70% by weight relative to the total weight of the cleaning mixture thus obtained;
said assemblies are subjected to a co-solvent cleaning treatment in vapor phase with said cleaning mixture at a temperature between 60° C. and 75° C., for 3 min to 10 min.

As just seen, the composition according to the invention has the advantage of being able to be implemented in most of the existing defluxing methods. It makes it possible to clean a wide range of creamy or liquid flux residues (including resinous fluxes), used in electronics, whether polar or apolar, and in particular leaded, unleaded, water-soluble or other fluxes. In addition, it may be used in a wide range of temperatures, subject to adaptation of the cleaning time.

Another notable advantage of the composition according to the invention is that it is compatible with most of the materials used for the manufactures of boards and other electronic assemblies, such as certain polymers of the components and metals. Thus, the methods according to the present invention may apply to the treatment of assemblies comprising elements made of polymers, copper, aluminum, brass, or other metals.

It is added that, in addition to the properties mentioned above, the composition that has just been described and the cleaning products comprising it, meet the current constraints of the manufacturers of printed circuit boards and other electronic assemblies in relation to HSE (Health-Safety-Environment) standards. Indeed, the compounds used in the selected formulations are not corrosive like conventional cleaners, although they do retain an irritating effect. In addition, the composition is compliant with the REACH directives.

The composition according to the invention and the associated methods have multiple applications. They are suitable for the defluxing of a wide variety of electronic assemblies. In particular, they may be used in the manufacture of electronic devices of the printed circuit board (PCB), in-package systems (or SIP for System In Package), insulated-gate bipolar transistors (IGBT), semiconductor components, etc. type.

They are used primarily for cleaning printed circuits, but also for cleaning badly printed circuits. They may also be used for equipment maintenance cleaning (cleaning of oven parts, wave soldering frames, etc.). The composition may also be used in other cleaning applications belonging to the mechanical, medical, or other domain.

The present invention will be better understood, and details thereof will appear, in light of the description that will be made of different embodiment variants.

### EXAMPLE 1

The compositions hereinafter may be used in the framework of the present invention. All contents are given in weight relative to the total weight of the composition.

### Composition C1

70%-85% dipropylene glycol monopropyl ether
13%-25% of 2,5,7,10 tetraoxaundecane
1%-5% of phosphoric acid 2-ethylhexyl ester

### Composition C2

70%-85% dipropylene glycol monopropyl ether
13%-25% dimethylsulfoxide
1%-5% of phosphoric acid 2-ethylhexyl ester

### Composition C3a

70%-85% hexylene glycol
13%-25% of 2,5,7,10 tetraoxaundecane
1%-5% of phosphoric acid 2-ethylhexyl ester

### Composition C3b

30%-42.5% dipropylene glycol monopropyl ether
30%-42.5% dipropylene glycol monobutyl ether
13%-25% of 2,5,7,10 tetraoxaundecane
1%-5% of phosphoric acid 2-ethylhexyl ester

### Composition C4a

95%-99% dipropylene glycol monobutyl ether
1%-5% of phosphoric acid 2-ethylhexyl ester

### Composition C4b

95%-99% dipropylene glycol monobutyl ether
1%-5% of phosphoric acid 2-ethylhexyl ester

### Composition C5

70%-85% dipropylene glycol monopropyl ether
13%-25% dibasic ester mixture
1%-5% of phosphoric acid 2-ethylhexyl ester

### Composition C6a

70%-85% dipropylene glycol monopropyl ether
13%-25% tetraoxaundecane
1%-5% phosphoric acid

### Composition C6b

70%-85% dipropylene glycol monopropyl ether
13%-25% tetraoxaundecane
1%-5% gluconic acid

### Composition C7

70% dipropylene glycol monopropyl ether
20% 1,3-dioxolane
10% phosphoric acid 2-ethylhexyl ester

### Composition C8

80% dipropylene glycol monobutyl ether
10% 1,3-dioxolane
10% phosphoric acid 2-ethylhexyl ester

### Acid Value

The acid value of the compositions C1 and C7 was measured.

Acid value C1 pure: 8.4 mgKOH/g

Acid value C7 pure: 31 mgKOH/g

### Performance Tests

Performance tests of these defluxing compositions were conducted according to the following protocol. Electronic components were assembled using a solder cream or a flux, according to the cases, on template boards or coupons.

For the immersion tests:

The coupons are immersed in beakers containing the compositions to be tested at the chosen dilution and temperature, for a predefined period of time after which the quality of the cleaning is evaluated, or for a period of time necessary for the quality to be satisfactory.

For the immersion tests:

The coupons are immersed in beakers containing the compositions to be tested at the chosen dilution and temperature, for a predefined period of time after which the quality of the cleaning is evaluated, or for a period of time necessary for the quality to be satisfactory.

For the spray tests:

Aqueous spray cleaning is performed by placing the coupons in a spraying machine in cycle. Spraying is done using nozzles, under pressure of a few bars for 5 min to 10 min, and is followed by rinsing with water and drying.

For solvent or co-solvent tests:

The boards are placed in a basket and immersed in a first tank containing the solvents in a mixture (washing, zone 1) for a determined time, then the basket is removed and drained 30 seconds before being immersed in the rinsing bath (zone 2) for 2 minutes. The basket is then placed in the chamber (zone 3) where it is subjected to the vapor phase at approx. 55° C., also for two minutes. Finally, it is held for a few seconds to one minute in the cold zone (zone 4) to dry the boards.

Reading the results:

Defluxing effectiveness is assessed under a binocular microscope. Four levels of cleaning are distinguished, quantified from 1 to 4, with 1: perfect cleaning—2: traces of residue—3: poor cleaning—4: not cleaned.

### EXAMPLE 2: INFLUENCE OF THE MAIN SOLVENT

The compositions C1, C2, C3a and C3b, formulated in accordance with Example 1, were evaluated for their ability to dissolve resinous fluxes (FR) and commercial solder creams. The tested creams are no-clean, lead-free alloy solder creams. For each of them, a 15% solution in deionized water was prepared and poured into a defluxing machine by spraying. Coupons containing a weld made using the cream or flux to be tested were subjected to the cleaning treatment in solutions at 55° C., for the time necessary to completely remove residues. The results are shown in Table 1.

TABLE 1

| | | Effective- | Effective- | Effective- | Effective- |
|---|---|---|---|---|---|
| | Time | ness of C1 | ness of C2 | ness of C3b | ness of C3a |
| cream 1 | 3 min. | 1 | | 1 | 3 |
| cream 2 | 3 min. | 1 | | 1 | 3 |
| cream 3 | 3 min. | 1 | | 1 | 3 |
| cream 4 | 3 min. | 1 | | 1 | 3 |
| FR 1 | 10 min. | 1 | | 1 | 4 |
| FR 2 | 3 min. | 1 | | 1 | 4 |
| FR 3 | 5 min. | 1 | | 1 | 4 |

Results: Observation under a binocular microscope shows effectiveness rated as 1, with an identical cleaning quality for the compositions comprising one of dipropylene glycol monobutyl ether and the other of dipropylene glycol monopropyl ether as the main solvent. All the creams tested were able to be cleaned most often in just 3 minutes and in 10 minutes maximum, against a time commonly between 10 min and 15 min. Other glycol ethers, such as hexylene glycol, were tested and do not have the same cleaning effectiveness in this formulation.

### EXAMPLE 3: INFLUENCE OF THE SECONDARY SOLVENT

The compositions C1, C2 and C5, formulated in accordance with Example 1 were evaluated for their ability to dissolve a commercially available solder cream (no-clean lead-free alloy solder cream). For each of them, a 15% solution in deionized water was prepared in a beaker and heated to 55° C. Coupons comprising a weld carried out using the cream were immersed in the solutions for 15 min.

Results: Observation under a binocular microscope shows an effectiveness level 1, with an identical cleaning quality for the compositions comprising one oftetraoxaundecane, the second of dimethylsulfoxide, and the last a mixture of dibasic esters, as a secondary solvent.

### EXAMPLE 4: COMPOSITIONS WITH ONE SOLVENT (WITHOUT SECONDARY SOLVENT)

The compositions C4a and C4b formulated as indicated in Example 1 were evaluated for their ability to dissolve commercially available solder creams (no-clean lead-free alloy solder creams). A solution of each composition was prepared in a beaker by 15% dilution by weight in deionized water and heating to 55° C. Coupons comprising a weld carried out with each of the creams were immersed in the solutions for 15 min.

Results: Observation under a binocular microscope shows and effectiveness level 1 for both creams. The compositions such as C4a and C4b comprising a main solvent and the additive, but without a secondary solvent, provide perfect satisfaction for the defluxing of solder creams. This thus shows that the combination of the main solvent and the additive is very effective in terms of residue removal. The adding of the secondary solvent is essential to facilitate rinsing. It has been shown that different ratios may be used. Indeed, the effectiveness of the rinsing is directly proportional to the concentration of secondary solvent, but above 40% by weight in relation to glycol ether, the effectiveness of the first solvent is reduced. Those skilled in the art will be able to define the most suitable ratios for each case, according to their objectives and the technical constraints encountered.

### EXAMPLE 5: INFLUENCE OF THE NATURE AND ADDITIVE ACID CONCENTRATION

The compositions C1, C6a and C6b formulated as indicated in Example 1 were evaluated for their ability to dissolve a commercially available solder cream (no-clean lead-free alloy solder cream). For each of the compositions, a 15% solution by weight in deionized water was prepared in a beaker and heated to 55° C. Coupons comprising a weld carried out using the cream were immersed in the solutions for 15 min.

Results: Observation under a binocular microscope shows that all compositions allowed flux residues to be removed, but with unequal results. Indeed, and effectiveness level 1 is obtained for composition C1, but only level 2 for C6a and level 3 for C6b. A cleaning action occurred even at low phosphoric ester contents (as low as 0.5%). Other acids have been tested, such as phosphoric acid or gluconic acid, revealing a lower cleaning effectiveness, of levels 2 and 3 respectively after binocular inspection.

### EXAMPLE 6: COMPARATIVE EFFECTIVENESS OF DEFLUXING PRODUCTS OF DIFFERENT PH VALUES

Commercially available detergents were compared to the compositions C1 and C7 in a lead-free solder cream cleaning test. The cream was applied to coupons, which after being placed in a reflux oven, were left at rest for at least 2 hours. Then, they were subjected to immersion cleaning without stirring, at 55° C., until total removal of the residues, within the limit of 15 min. The results are shown in Table 2.

TABLE 2

| | Detergent | Detergent | Detergent | Compo- | Compo- |
|---|---|---|---|---|---|
| | 1 | 2 | 3 | sition | sition |
| | alkaline | alkaline | pH | C1 | C7 |
| | pH | pH | neutral | acid pH | acid pH |
| Cream | diluted to | diluted to | diluted to | diluted to | diluted to |
| type | 25% | 25% | 15% | 15% | 15% |
| pH or pH | 10-12 | 10-12 | 6-8 | 3.0 | 2.5 |
| range | | | | | |
| Cleaning | 15 min | 15 min | 15 min | 8 min. | 8 min. |
| duration | | | | | |
| Quality of | 2 | 2 | 1-2 | 1 | 1 |
| the | | | | | |
| cleaning | | | | | |

Results: Observation under a binocular microscope shows and effectiveness level 1 after 8 min for composition C1, whereas with commercial alkaline or neutral products, the persistence of a small amount of residue is observed, even after 15 min.

### EXAMPLE 7: STRIPPING SPEED OF DIFFERENT FLUXES

The compositions C1, C7 or C8 formulated in accordance with Example 1 were evaluated for their ability to dissolve different stripping fluxes, namely a) liquid fluxes diluted in water or alcohol, halogen-free and lead-free, suitable for conventional wave soldering or selective wave soldering; b) resinous fluxes, which are low-viscosity liquid sticky fluxes without cleaning. Coupons previously subjected to a treatment by each of the fluxes tested were subjected to a spray treatment of each of the compositions C1, C7 and C8 diluted to 15% by weight in deionized water, at 55° C., for the time necessary for total removal of the residues of these fluxes (quality level 1). The results are shown in Tables 3 and 4.

TABLE 3

| Type | Reference | Duration C1 |
|---|---|---|
| Alcohol base flux (FA) | FA 1 | 3 min. |
| | FA 2 | 3 min. |
| Water base flux (FE) | FE 1 | 5 min. |
| | FE 2 | 5 min. |
| Resinous flux (FR) | FR 1 | 8 min. |
| | FR 2 | 8 min. |
| | FR 3 | 8 min. |
| | FR 4 | 8 min. |

TABLE 4

| Type | Reference | Duration C7 | Duration C8 |
|---|---|---|---|
| Alcohol base flux | Ecofrec 205 ™ | 3 min. | 3 min. |
| (FA) | FA 2 | 3 min. | 3 min. |
| Water base flux | Ecofrec 320 ™ | 5 min. | 5 min. |
| (FE) | FE 2 | 5 min. | 5 min. |
| Resinous flux | Ecofrec TF 37i ™ | 8 min. | 8 min. |
| (FR) | FR 2 | 8 min. | 8 min. |
| | Ecofrec TF 49 ™ | 8 min. | 8 min. |
| Other fluxes | Alpha WSX-9284 | 5 min. | 5 min. |
| | Kester TSF | 8 min. | 8 min. |
| | 6522RH | | |

Results: All of the fluxes tested may be cleaned with the compositions C1, C7 or C8. Effectiveness level 1 is achieved in under 10 minutes in all cases, which is clearly faster than stripping with the known products. The times of 3 min. and 5 min. for the removal of alcohol-based and water-based liquid fluxes, respectively, are particularly remarkable.

### EXAMPLE 8: CLEANING SPEED OF DIFFERENT CREAMS

The compositions C1, C7 and C8 formulated as indicated in Example 1 were tested with different types of lead-free solder creams and lead-based solder creams (tin-lead-based alloy), commercially available. The filler metal is a tin-silver-copper alloy of the SAC type, or a lead-based alloy of the SPA type. Coupons comprising a weld carried out using each cream were subjected to a spray treatment for 15 min in a solution of each of the compositions C1, C7 and C8 diluted to 15% by weight in deionized water, and heated to 55° C., for the time necessary for the total removal of residues (quality level 1). The results are shown in Tables 5 and 6.

TABLE 5

| | | | Duration |
|---|---|---|---|
| Type | Reference | Filler metal | C1 |
| Creams | Cream 1 | SAC T4 | 3 min. |
| lead-free | Cream 2 | SAC T4 | 3 min. |
| | Cream 3 | SAC T4 | 3 min. |
| | Cream 4 | SAC | 3 min. |
| | Cream 5 | SAC T4 | 3 min. |
| Creams with | Cream 6 | SPA T3 | 3 min. |
| lead | Cream 7 | SPA T3 | 3 min. |

TABLE 6

| | | Filler | Duration | Duration |
|---|---|---|---|---|
| Type | Reference | metal | C7 | C8 |
| Creams | Cream 3 | SAC T4 | 3 min. | 3 min. |
| lead-free | Cream 4 | SAC T4 | 3 min. | 3 min. |
| | Ecorel 305-21 | SAC T4 | 3 min. | 3 min. |
| | Ecorel 305-16 | SAC T4 | 3 min. | 3 min. |
| | LVD | | | |
| | Heraeus F590 | SAC T4 | 3 min. | 3 min. |
| | SA305C-89M5 | | | |
| Creams with | Cream 6 | SPA T3 | 3 min. | 3 min. |
| lead | Ecorel easy | SPA T3 | 3 min. | 3 min. |
| | 803M | | | |

Results: All the creams tested may be cleaned with the composition C1, C7 and C8. Effectiveness level 1 is achieved in all cases within 3 minutes, which is clearly faster than with the known products on the market.

### EXAMPLE 9: COMPARATIVE CLEANING TEST BY CO-SOLVENT TECHNIQUE

The composition C8 formulated as indicated in Example 1 was evaluated for its ability to remove varied flux residues (creams and resinous fluxes) in a method with co-solvent (water-free). The composition C8 was mixed with the co-solvent which is here a hydrofluoroether (HFE), with a mass proportion of 60/40. The mixture was poured into the tank of the Apparatus provided for this purpose and the rinsing tank was filled with rinsing product alone, namely also HFE. The tests are conducted as described in Example 1, unless indicated otherwise, on the one hand with the composition C8 and on the other hand with a commercially available product, among the most effective known. The results are given in Table 7.

TABLE 7

| | | | Effectiveness |
|---|---|---|---|
| | Time | | Commercially- |
| | in each | Effectiveness | available |
| | zone | C8 + HFE | product + HFE |
| Flux Ref. | (min) | co-solvent | co-solvent |
| Ecorel free 305-16 | 3-2-2-1 | 1 | 2 |
| LVD | | | |
| Ecorel free 305-21 | 3-2-2-1 | 1 | 1 |
| Cream 3 | 3-2-2-1 | 1 | 1 |
| Cream 4 | 3-2-2-1 | 1 | 1 |
| Ecorel easy 803M | 5-2-2-1 | 1 | 1 |
| Cream 6 | 5-2-2-1 | 3 | 3 |
| Ecofrec TF 37i ™ | 3-2-2-1 | 1 | 1 |
| FR 2 | 3-2-2-1 | 1 | 1 |
| Ecofrec TF 49 ™ | 3-2-2-1 | 1 | 1 |

Results: Observation under a binocular microscope shows an effectiveness noted as 1 for most of the fluxes tested. A similar effectiveness is obtained here, but with the notable advantage that the cleaning mixture based on the composition C8 has clearly less risk of use than the commercially available product.

### EXAMPLE 10: CLEANING TEST BY IMMERSION TECHNIQUE WITH IMMERSED JETS

The composition C1 formulated as indicated in Example 1 was evaluated as a function of its dilution (10% and 15% by weight) and temperature, for its ability to remove residues from two fluxes (cream 9; cream 4) in an aqueous immersion cleaning method with immersed jets. The applied treatment time was 5 min, 10 min or 15 min. The tests were carried out in baths used for 24 hours and for 1 week. The results are provided in Table 8.

TABLE 8

| | dilution | T | Time in | cream 9 | cream 1 | cream 9 | cream 1 |
|---|---|---|---|---|---|---|---|
| | % | ° C. | minutes | 24 h | 24 h | 1 week | 1 week |
| Bath 1 | 10 | 55 | 5 | 1 | 1.5 | 1 | 1.5 |
| Bath 2 | 10 | 55 | 10 | 1 | 1.5 | 1 | 1.5 |
| Bath 3 | 15 | 55 | 10 | 1 | 1.5 | 1 | 1.5 |
| Bath 4 | 15 | 55 | 5 | 1 | 1.5 | 1 | 1.5 |
| Bath 5 | 15 | 30 | 15 | 1 | 1.5 | 1 | 1.5 |
| Bath 6 | 15 | 30 | 10 | 1.5 | 2 | 2 | 2 |
| Bath 7 | 10 | 30 | 10 | 1.5 | 2 | 2 | 2 |
| Bath 8 | 10 | 30 | 15 | 1 | 1.5 | 1 | 1.5 |

Results: It is noted that a 15% dilution often results in a better service life of the bath. In addition, low temperatures (30° C.) also allow defluxing, although a slightly longer time is required to achieve maximum effectiveness.

1. Composition for cleaning contaminants and flux residues on electronic assemblies, wherein to the total weight of the composition comprises:
from 20% to 99.5% by weight of a main solvent consisting of at least one C6-C15 glycol ether, and optionally a secondary solvent,
from 0.5% to 20% by weight of an acid additive being a phosphoric acid ester.

2. Composition according to claim 1, wherein the said acid additive is a phosphoric acid ester of general formula R1-O—POOH—O—R2, wherein R1 represents a C1-C25 radical and R2 is a hydrogen atom, or wherein R1 and R2 represent identical or different C1-C25 radicals.

3. Composition according to claim 1, wherein the said acid additive is a phosphoric acid ester of general formula R1-O—POOH—O—R2, wherein R1 represents a C4-C16 radical and R2 is a hydrogen atom, or wherein R1 and R2 represent identical or different C4-C16 radicals.

4. Composition according to claim 1, wherein said acid additive is selected from phosphoric acid 2-ethylhexyl ester; poly(oxy-1.2-ethanediyl), phosphoric acid alpha-(2-ethylhexyl)-omega ester; phosphoric acid n-octyl ester; phosphoric acid methyl ester; phosphoric acid polyoxyethylene monooleyl ether; or a mixture thereof.

5. Composition according to claim 1, wherein the main solvent is a C6-C10 glycol ether or a mixture of two C6-C10 glycol ethers, each chosen from a tripropylene glycol, dipropylene glycol, propylene glycol, diethylene glycol, ethylene glycol or butylene glycol ether.

6. Composition according to claim 1, wherein the glycol ether is selected from tripropylene glycol n-butyl ether; dipropylene glycol monomethyl ether; dipropylene glycol dimethyl ether; dipropylene glycol monopropyl ether; dipropylene glycol n-butyl ether; dipropylene glycol phenyl ether; propylene glycol propyl ether; propylene glycol n-butyl ether; propylene glycol phenyl ether; diethyleneglycol monobutyl ether; diethyleneglycol monohexyl ether; diethyleneglycol phenyl ether; ethyleneglycol mono tert-butyl ether; ethyleneglycol monohexyl ether; ethyleneglycol phenyl ether; butyleneglycol phenyl ether.

7. Composition according to claim 1, wherein it comprises from 1% to 70% of a secondary solvent chosen from a dibasic ester, a C3-C20 acetal, dimethyl sulfoxide, or a mixture thereof.

8. The composition according to claim 1, wherein that the secondary solvent is selected from tetraoxaundecane; dimethoxymethane; diethoxymethane; dipropoxymethane; dibutoxymethane, 2-ethyl hexylal; 1.3-dioxolane, or a mixture thereof.

9. Composition according to claim 1, wherein it comprises, relative to the total weight of the composition:
from 40% to 90% by weight of said main solvent,
from 7% to 50% by weight of said secondary solvent, and
from 0.5% to 15% by weight of said acid additive.

10. Composition according to claim 1, wherein it comprises, relative to the total weight of the composition:
from 65% to 90% by weight of said main solvent,
from 9% to 30% by weight of said secondary solvent, and
from 1% to 15% by weight of said acid additive.

11. Composition according to claim 1, wherein it comprises, relative to the total weight of the composition:
from 60% to 98% by weight of a C6-C10 glycol ether chosen from tripropylene glycol, dipropylene glycol, propylene glycol, diethylene glycol, ethylene glycol or butylene glycol ether
from 1% to 25% by weight of a secondary solvent chosen from 1,3-dioxolane, tetraoxaundecane, dimethylsulfoxide, a dibasic ester, or a mixture thereof, and
from 1% to 15% by weight of a phosphoric acid ester.

12. Composition according to claim 1, wherein it comprises, relative to the total weight of the composition:
from 90% to 99.5% by weight of said main solvent,
from 0.5% to 10% by weight of said acid additive.

13. Composition according to claim 1, wherein it has an acid value less than or equal to mgKOH/g; preferably between 1.8 and 50 mgKOH/g.

14. Defluxing product for electronic assemblies, wherein a composition, comprises, according to claim 1, and wherein:
said composition is pure; or
said composition is diluted in water to obtain a cleaning solution having a pH less than or equal to 5; or
said composition is mixed with a fluorinated or chlorinated rinsing co-solvent.

15. Aqueous method for cleaning contaminants and flux residues on electronic assemblies, wherein the steps consisting of:
obtaining a composition according to claim 1 and diluting it in water to obtain a cleaning solution of a concentration between 5% and 30% by weight relative to the total weight of the solution,
subjecting said assemblies to a cleaning treatment by immersion or by spraying with said cleaning solution at a temperature between 30° C. and 70° C., for 1 min to 20 min.

16. Aqueous cleaning method according to claim 15, wherein the:
said composition is diluted in water to obtain a cleaning solution of a concentration between 10% and 20% by weight relative to the total weight of the solution, and/or
said assemblies are subjected to a cleaning treatment by immersion or by spraying with said cleaning solution at a temperature between 50° C. and 65° C., for 3 min to 10 min.

17. Anhydrous method for cleaning contaminants and flux residues on electronic assemblies, wherein the steps consisting of:
obtaining a composition according to claim 1 and a fluorinated rinsing co-solvent,
subjecting said assemblies to a vapor phase co-solvent cleaning treatment with said composition and said co-solvent, used successively or simultaneously, at a temperature between 50° C. and 80° C., for 1 min to 20 min.

18. Anhydrous cleaning method according to claim 17, wherein the:
said composition is mixed with a co-solvent chosen from hydrofluoroethers, hydrofluorocarbons or hydrofluorolefins, the composition representing from 50% to 70% by weight relative to the total weight of the cleaning mixture thus obtained;
said assemblies are subjected to a co-solvent cleaning treatment in vapor phase with said cleaning mixture at a temperature between 60° C. and 75° C., for 3 min to 10 min.
